(19) United States
(12) Patent Application Publication
(10) Pub. No.: US 2016/0314821 A1
(43) Pub. Date: Oct. 27, 2016

(54) METHOD FOR ACCESSING MULTI-PORT MEMORY MODULE, METHOD FOR INCREASING WRITE PORTS OF MEMORY MODULE AND ASSOCIATED MEMORY CONTROLLER

(71) Applicants: MEDIATEK INC., Hsin-Chu (TW); National Chiao Tung University, Hsinchu (TW)

(72) Inventors: Kuo-Cheng Lu, Hsinchu City (TW); Bo-Cheng Lai, Hualien County (TW); Kun-Hua Huang, Taipei City (TW); Jiun-Liang Lin, Taipei City (TW)

(21) Appl. No.: 15/098,330

(22) Filed: Apr. 14, 2016

Related U.S. Application Data
(60) Provisional application No. 62/150,862, filed on Apr. 22, 2015.
(60) Provisional application No. 62/195,796, filed on Jul. 23, 2015.

(51) Int. Cl. G11C 7/10; G11C 11/406

(52) U.S. Cl. CPC G11C 7/1075; G11C 7/1072; G11C 11/40615; G11C 11/40618

(57) ABSTRACT

A method for accessing a multi-port memory module comprising a plurality of banks is provided, wherein the plurality of banks comprise at least a first bank, a second bank and a reference bank, and the method comprises: when first data is requested to be written into the first bank, reading reference data from the reference bank, and encoding the first data with the reference data to generate first encoded data, and writing the first encoded data into the first bank; and when second data is requested to be written into the second bank, reading the same reference data from the reference bank, and encoding the second data with the reference data to generate second encoded data, and writing the second encoded data into the second bank.

### CROSS REFERENCE TO RELATED APPLICATIONS

This application claims the priority of U.S. Provisional Application No. 62/150,862, filed on Apr. 22, 2015, and the priority of U.S. Provisional Application No. 62/195,796, filed on Jul. 23, 2015, which are included herein by reference in its entirety.

### BACKGROUND

A multi-port memory module generally comprises a plurality of banks for storing data, and each bank is allowed to be accessed independently. Each bank also supports several read command(s) and write command(s), for example, if the bank is a two-read-one-write (2R1W) bank having two read ports and one write port, the bank can execute two read commands and one write command simultaneously. However, when the memory receives two or more write commands to write data into a single bank, a bank conflict occurs and the write commands are required to be sequentially executed, causing memory access latency and worse memory access efficiency. To solve this problem, the conventional multi-port memory module uses a customized circuit to enable multiple access ports, or assigns more memory cells (e.g. auxiliary bank or backup bank corresponding to the master bank) to support more concurrent accesses. These methods, however, may increase the design and manufacture cost and/or increase the chip area and power consumption. Therefore, how to provide to a memory control method to extend the write ports of the memory module is an important topic.

### SUMMARY

It is therefore an objective of the present invention to provide a method for accessing a multi-port memory module, which can increase the write ports of the memory module without increasing the manufacturing cost too much, to solve the above-mentioned problems.

According to one embodiment of the present invention, a method for accessing a multi-port memory module comprising a plurality of banks is provided, wherein the plurality of banks comprise at least a first bank, a second bank and a reference bank, and the method comprises: when first data is requested to be written into the first bank, reading reference data from the reference bank, and encoding the first data with the reference data to generate first encoded data, and writing the first encoded data into the first bank; and when second data is requested to be written into the second bank, reading the same reference data from the reference bank, and encoding the second data with the reference data to generate second encoded data, and writing the second encoded data into the second bank.

According to another embodiment of the present invention, a memory controller coupled to a multi-port memory module comprising a plurality of banks is provided, wherein the plurality of banks comprise at least a first bank, a second bank and a reference bank. When first data is requested to be written into the first bank, the memory controller is arranged to read reference data from the reference bank, and encode the first data with the reference data to generate first encoded data, and write the first encoded data into the first bank; and when second data is requested to be written into the second bank, the memory controller is arranged to read the same reference data from the reference bank, and encode the second data with the reference data to generate second encoded data, and write the second encoded data into the second bank.

According to another embodiment of the present invention, a method for increasing write ports of a memory module is provided, wherein the method comprises: providing a first bank and a reference bank within the memory module, wherein the first bank comprises K write ports, and the reference bank comprises N read ports; when both first data and second data are requested to be written into the first bank, but the second data is not allowed to be written into the first bank to update/overwrite old data simultaneously, reading a first reference data from the reference bank, encoding the first data with the first reference data to generate a first encoded data, and writing the first encoded data into the first bank; and reading the old data from the first bank, encoding the second data with the old data to generate a second encoded data, and writing the second encoded data into the reference bank to update/overwrite a second reference data corresponding to the old data.

According to another embodiment of the present invention, a memory controller coupled to a multi-port memory module is provided. The memory module comprises a first bank and a reference bank, wherein the first bank comprises K write ports, and the reference bank comprises N read ports. When both first data and second data are requested to be written into the first bank, but the second data is not allowed to be written into the first bank to update/overwrite old data simultaneously, the memory controller reads a first reference data from the reference bank, encodes the first data with the first reference data to generate a first encoded data, and writes the first encoded data into the first bank; and reads the old data from the first bank, encoding the second data with the old data to generate a second encoded data, and writing the second encoded data into the reference bank to update/overwrite a second reference data corresponding to the old data.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a memory controller according to one embodiment of the present invention.

FIG. 2A is a diagram illustrating a method for accessing the memory module according to one embodiment of the present invention.

FIG. 2B is a diagram illustrating a method for reading the data stored in the banks shown in FIG. 2A according to one embodiment of the present invention.

FIG. 3A is a diagram illustrating a method for accessing the memory module according to another embodiment of the present invention.

FIG. 3B is a diagram illustrating a method for reading the data stored in the banks shown in FIG. 3A according to one embodiment of the present invention.

FIG. 4 is a diagram illustrating a method for accessing the memory module when two data D2 and D3 are required to be written into the bank 210 according to one embodiment of the present invention.

FIG. 5 is a diagram showing the banks 210 and 220 and the reference bank 230 when two data D2 and D3 are written into the memory module.

FIG. 6 is a flowchart of a method for accessing the memory module according to one embodiment of the present invention.

FIG. 7 is a diagram illustrating a method for reading the data stored in the banks 210 and 220 shown in FIGS. 4 and 5 according to one embodiment of the present invention.

FIG. 8 is a diagram showing operations of banks and a reference bank, when two data D4 and D5 are asked to be written into the same bank.

FIG. 9 is a diagram illustrating a method for accessing the memory module according to another embodiment of the present invention.

FIG. 10 is a diagram illustrating a method for accessing the memory module according to another embodiment of the present invention.

FIG. 11 is a diagram illustrating a method for accessing the memory module according to another embodiment of the present invention.

FIG. 12 is a diagram illustrating a method for accessing the memory module according to another embodiment of the present invention.

FIG. 13 is a diagram showing that a NR1W reference bank and two MR1W banks form a (N-2)R&2W specific memory module.

FIG. 14 is a diagram showing that a NR2W reference bank and two MR2W banks form a (N-4)R&4W specific memory module.

FIG. 15 is a diagram illustrating the write ports extensions according to one embodiment of the present invention.

### DETAILED DESCRIPTION

Certain terms are used throughout the following description and claims to refer to particular system components. As one skilled in the art will appreciate, manufacturers may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ” The terms “couple” and “couples” are intended to mean either an indirect or a direct electrical connection. Thus, if a first device couples to a second device, that connection may be through a direct electrical connection, or through an indirect electrical connection via other devices and connections.

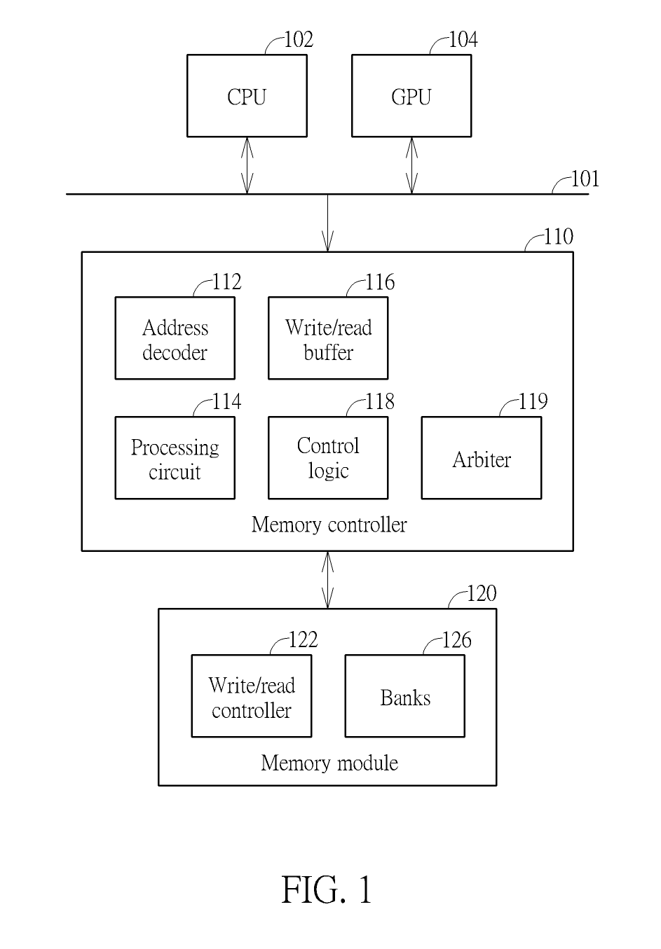

Please refer to FIG. 1, which is a diagram illustrating a memory controller 110 according to one embodiment of the present invention. As shown in FIG. 1, the memory controller 110 is coupled to a memory module 120, and is coupled to elements need to access the memory module 120 such as a central processing unit (CPU) 102 and a graphics processing unit (GPU) 104 via a bus 101. In addition, the memory controller 110 may comprises an address decoder 112, a processing circuit 114, a write/read buffer 116, a control logic 118 and an arbiter 119; and the memory module 120 comprises a write/read controller 122 and a plurality of banks 126. In this embodiment, the memory module 120 is a multi-port memory module supporting two or more read/write operations; and each of the banks 126 has independent read/write ports for supporting multiple accesses, and is allowed to be accessed independently. In addition, the memory module 120 may be a multi-port static random access memory (SRAM) module or a multi-port dynamic random access memory (DRAM), however, this is not a limitation of the present invention.

Regarding the operations of the elements within the memory controller 110, the address decoder 112 is arranged to decode a received signal from the CPU 102 or GPU 104 or the other elements required to access the memory module 120 to generate a plurality of read command(s) and/or write command(s); the processing circuit 114 is arranged to manage and process the read/write commands; the write/read buffer 116 is arranged to temporarily store the data to be written into the memory module 120 and/or to store the data read from the memory module 120; the control logic 118 is arranged to encode data to generate the encoded data in response to the write command, and to decode the encoded data read from the memory module 120 in response to the read command; and the arbiter 119 is arranged to schedule the write commands and the read commands.

Regarding the elements within the memory module 120, the write/read controller 122 may comprises a row decoder and a column decoder, and is arranged to decode the write/read command(s) from the memory controller 110 to access the bit(s) corresponding to the address within the banks 120 specified by the write/read command(s), and each of the banks 126 is implemented by one or more memory chips for storing data.

The embodiment of the present invention provides a method for accessing the memory module 120, the method can allow the memory module 120 to support more write commands (i.e. increase the write ports) while each of the banks 126 only has a less write port(s). For example, each of the banks 126 may only have one write port, but the memory module 120 may always support more write commands. Detailed descriptions about the embodiments of the present invention are as follows.

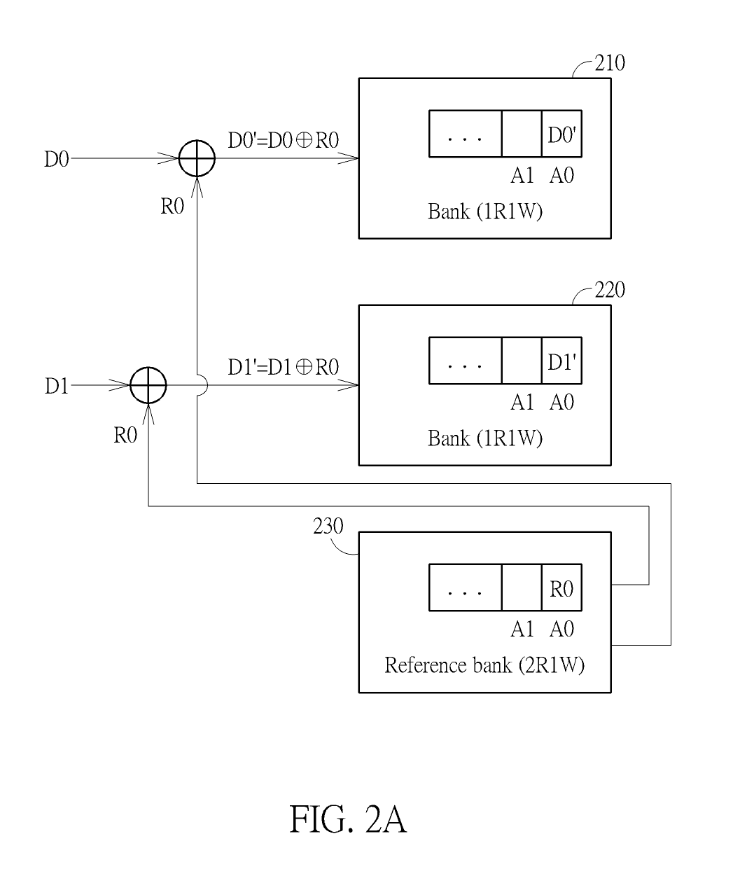

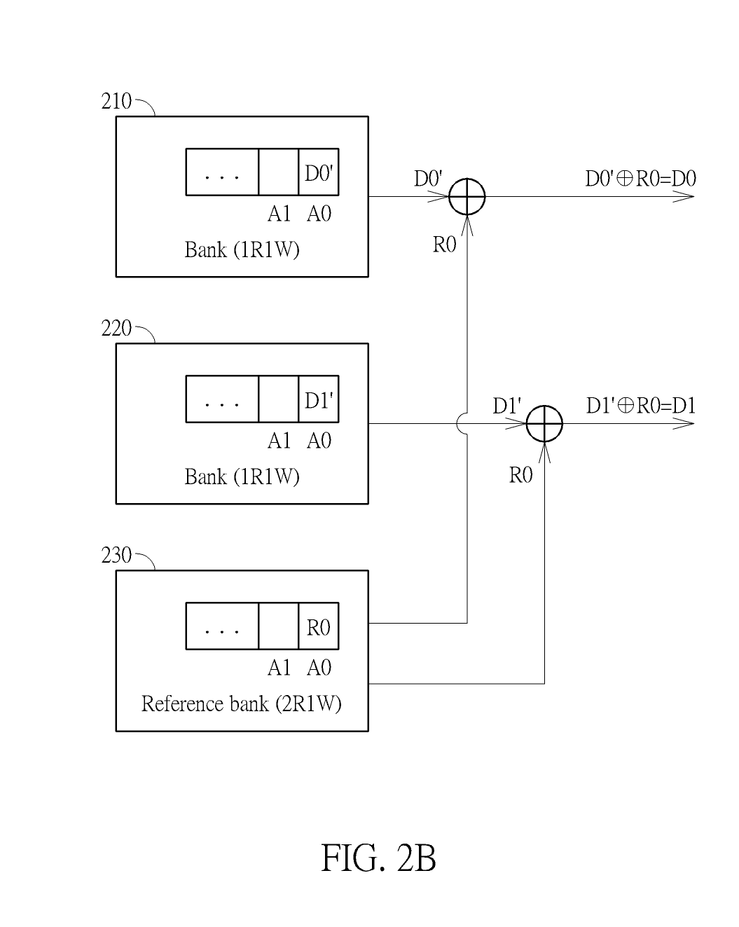

Please refer to FIG. 2A, which is a diagram illustrating a method for accessing the memory module 120 according to one embodiment of the present invention. As shown in FIG. 2A, the memory module 120 comprises two banks 210 and 220 and a reference bank 230, wherein the banks 210 and 220 are one-read-one-write (1R1W) banks, and the reference bank 230 is a two-read-one-write (2R1W) bank. As shown in FIG. 2A, when the memory module 120 receives two write commands and two data D0 and D1 are requested to be written into the banks 210 and 220, respectively, the memory controller 110 reads a reference data R0 from an address A0 of the reference bank 230, and the memory controller 110 encodes the data D0 with the reference data R0 to generate the encoded data D0′, and the encoded data D0′ is written into a cell having the address A0 of the bank 210; and at the same time, the memory controller 110 reads the same reference data R0 from the address A0 of the reference bank 230, and the memory controller 110 encodes the data D1 with the reference data R0 to generate the encoded data D1′, and the encoded data D1′ is written into a cell having the address A0 of the bank 220. In addition, in this embodiment, each of D0, D1, D0′, D1′ and R0 is a bit, and the encoding step is an exclusive-or (XOR) operation, that is D0′=D0^{⊕}R0, and D1′=D1^{⊕}R0, where the symbol “⊕” is an XOR operator.

The embodiment shown in FIG. 2A is a case that the write commands do not have the bank conflict issue, so the data D0 and D1 can be directly and simultaneously written into the banks 210 and 220, respectively, after the encoding steps.

Please refer to FIG. 2B, which is a diagram illustrating a method for reading the data stored in the banks 210 and 220 shown in FIG. 2A according to one embodiment of the present invention. A shown in FIG. 2B, when the memory module 120 receives two read commands and the two data D0 and D1 are requested to be read from the banks 210 and 220, respectively, the memory controller 110 reads the encoded data D0′ and the reference data R0 from the bank 210 and the reference bank 230, respectively, and the memory controller 110 decodes the encoded data D0′ by using the reference data R0 to generate the data D0; and at the same time, memory controller 110 further reads the encoded data D1′ and the reference data R0 from the bank 210 and the reference bank 230, respectively, and the memory controller 110 decodes the encoded data D1′ by using the reference data R0 to generate the data D1. In this embodiment, the decoding step is also the XOR operation, that is D0=D0′^{⊕}R0, and D1=D1′^{⊕}R0.

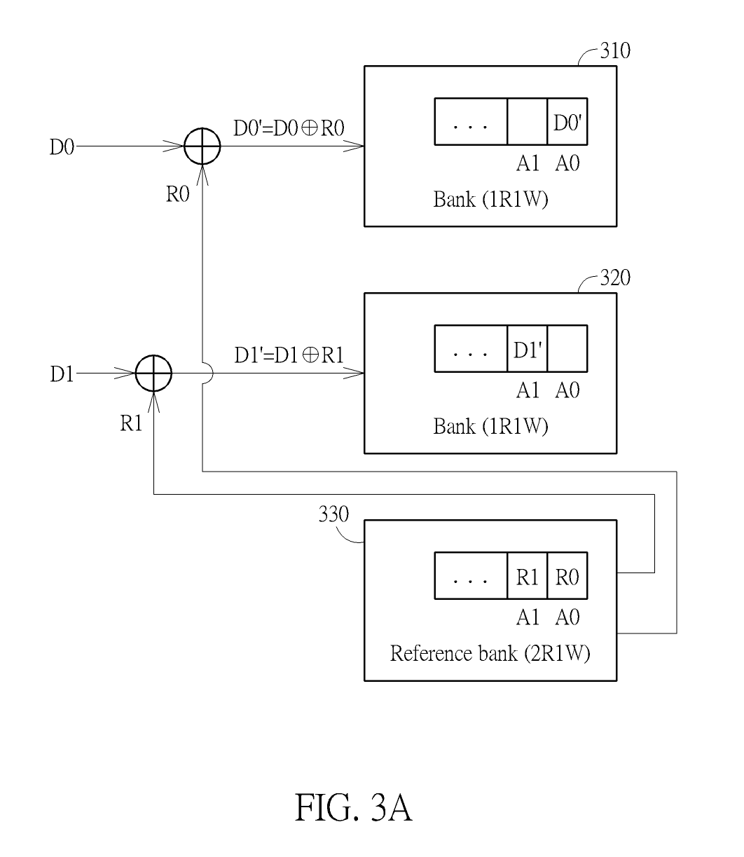

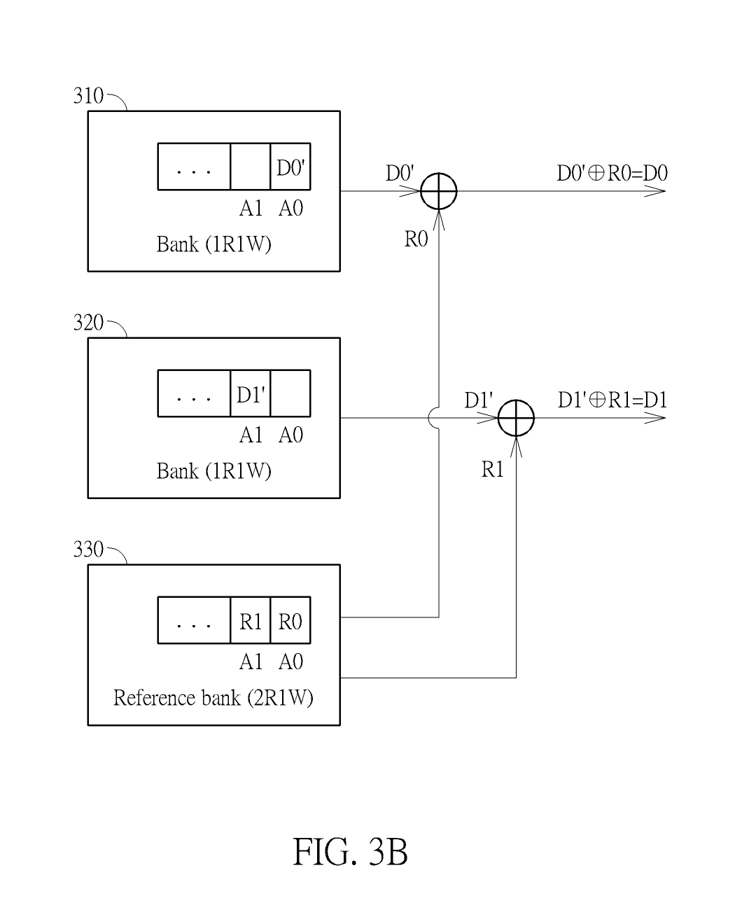

Please refer to FIG. 3A, which is a diagram illustrating a method for accessing the memory module 120 according to another embodiment of the present invention. As shown in FIG. 3A, the memory module 120 comprises two banks 310 and 320 and a reference bank 330, wherein the banks 310 and 320 are one-read-one-write (1R1W) banks, and the reference bank 330 is a two-read-one-write (2R1W) bank. As shown in FIG. 3A, when the memory module 120 receives two write commands and two data D0 and D1 are requested to be written into the banks 310 and 320, respectively, the memory controller 110 reads a reference data R0 from an address A0 of the reference bank 330, and the memory controller 110 encodes the data D0 with the reference data R0 to generate the encoded data D0′, and the encoded data D0′ is written into a cell having the address A0 of the bank 310; and at the same time, the memory controller 110 reads the reference data R1 from the address A1 of the reference bank 330, and the memory controller 110 encodes the data D1 with the reference data R1 to generate the encoded data D1′, and the encoded data D1′ is written into a cell having the address A1 of the bank 320. In addition, in this embodiment, each of D0, D1, D0′, D1′ and R0 is a bit, and the encoding step is the XOR operation, that is D0′=D0^{⊕}R0, and D1′=D1^{⊕}R1.

The embodiment shown in FIG. 3A is a case that the write commands do not have the bank conflict issue, so the data D0 and D1 can be directly and simultaneously written into the banks 310 and 320, respectively, after the encoding steps.

Please refer to FIG. 3B, which is a diagram illustrating a method for reading the data stored in the banks 310 and 320 shown in FIG. 3A according to one embodiment of the present invention. A shown in FIG. 3B, when the memory module 120 receives two read commands and the two data D0 and D1 are requested to be read from the banks 310 and 320, respectively, the memory controller 110 reads the encoded data D0′ and the reference data R0 from the bank 310 and the reference bank 330, respectively, and the memory controller 110 decodes the encoded data D0′ by using the reference data R0 to generate the data D0; and at the same time, memory controller 110 further reads the encoded data D1′ and the reference data R1 from the bank 310 and the reference bank 330, respectively, and the memory controller 110 decodes the encoded data D1′ by using the reference data R1 to generate the data D1. In this embodiment, the decoding step is also the XOR operation, that is D0=D0′^{⊕}R0, and D1=D1′^{⊕}R1.

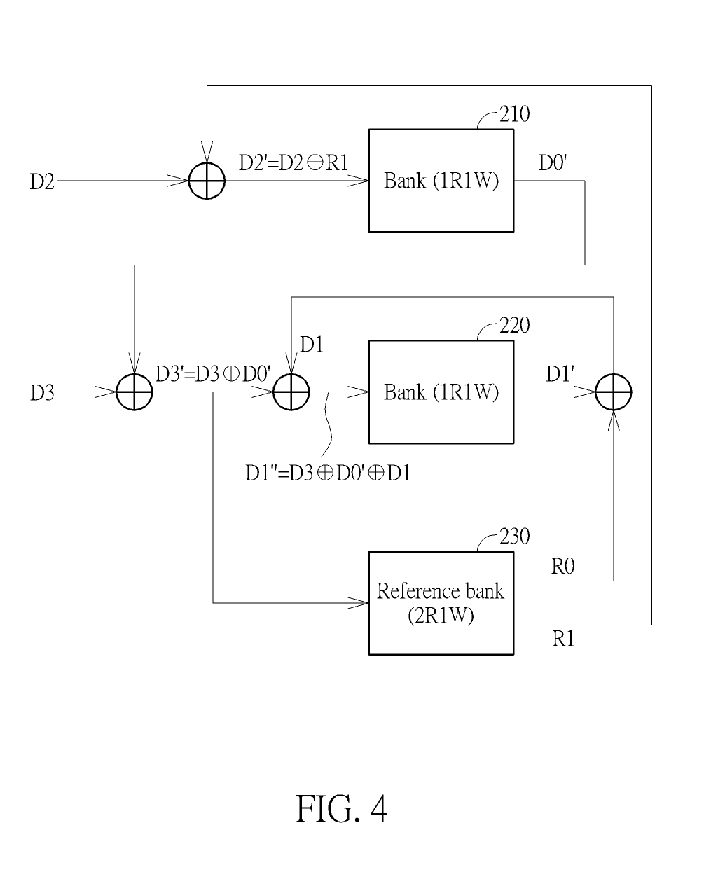

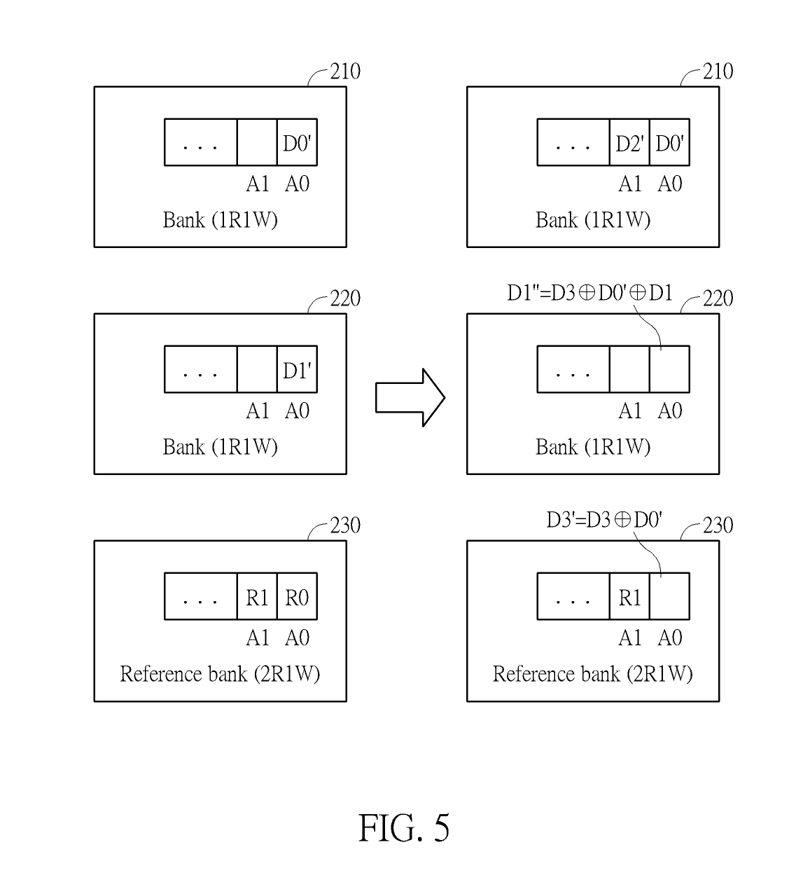

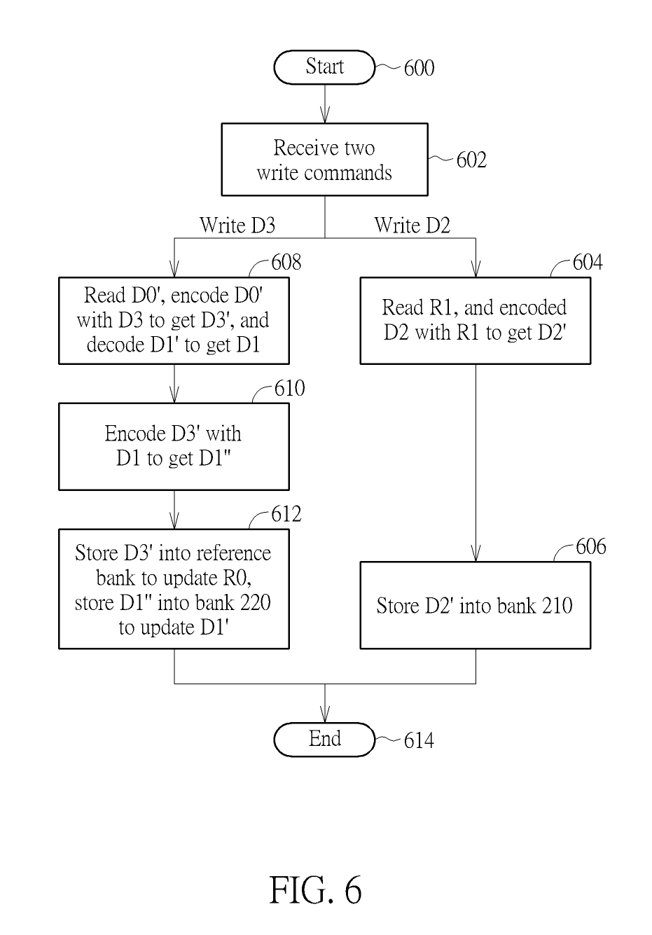

Please refer to FIGS. 4-6 to together, wherein FIG. 4 is a diagram illustrating a method for accessing the memory module 120 when two data D2 and D3 are required to be written into the bank 210 according to one embodiment of the present invention, FIG. 5 is a diagram showing the banks 210 and 220 and the reference bank 230 when two data D2 and D3 are written into the memory module, and FIG. 6 is a flowchart of a method for accessing the memory module according to one embodiment of the present invention, wherein the embodiment shown in FIGS. 4-6 follows the embodiment shown in FIG. 2A, that is the bank 210 originally stores the encoded data D0′ corresponding to the address A0, and the bank 220 originally stores the encoded data D1′ corresponding to the address A0.

In the Step 600, the flow starts. In Step 602, the memory module 120 receives two write commands from the memory controller 110. In this embodiment, one write command is to write the data D2 into a cell corresponding the address A1 of the bank 210, and the other write command is to write the data D3 into the cell corresponding the address A0 of the bank 210 (i.e. to update/overwrite the encoded D0′). Because the bank 210 is a 1R1W bank, so only one write command can be executed at the same time, therefore, only one of the data (D2 in this embodiment) is written into the bank 210 (Steps 604 and 606), and the other data (i.e. D3) is required to use a special flow (Steps 608-612) to be written into the memory module 120 simultaneously. In Step 604, the memory controller 110 reads a reference data R1 from a cell corresponding to the address A1 of the reference bank 230, and encodes the data D2 with the reference data R1 to generate an encoded data D2′. In Step 606, the memory controller 110 writes the encoded data D2′ into a cell corresponding to the address A1 of the bank 210. In this embodiment, the encoding step is the XOR operation, that is D2′=D2^{⊕}R1.

Regarding the data D3, in Step 608, the memory controller 110 reads the encoded data D0′ from the bank 210, and encodes the data D3 with the encoded data D0′ to generate an encoded data D3′, where the encoded data D3′ is to update/overwrite the reference data R0 stored in the reference bank 230; meanwhile, the memory controller 110 reads the encoded data D1′ and the reference data R0 from the bank 220 and the reference bank 230, respectively, and decodes the encoded data D1′ by using the reference data R0 to generate the data D1. In this embodiment, the encoding step and decoding step are the XOR operations, that is D3′=D3^{⊕}D0′, and D1=D1′^{⊕}R0.

In Step 610, the memory controller 110 encodes the encoded data D3′ with the data D1 to generate the updated encoded data D1″, which is to update to the encoded data D1′ stored in the bank 220. In this embodiment, the encoding step is the XOR operation, that is D1″=D3′^{⊕}D1=D3^{⊕}D0′^{⊕}D1.

In Step 612, the memory controller 110 writes the encoded data D3′ into the cell corresponding to the address A0 of the reference bank 230, that is to update/overwrite the reference data R0; and the memory controller 110 further writes the updated encoded data D1″ into the cell corresponding to the address A0 of the bank 220, that is to update/overwrite the encoded data D1′.

In Step 614, the two data D1 and D2 are written into the memory module 120 successfully, and the flow finishes.

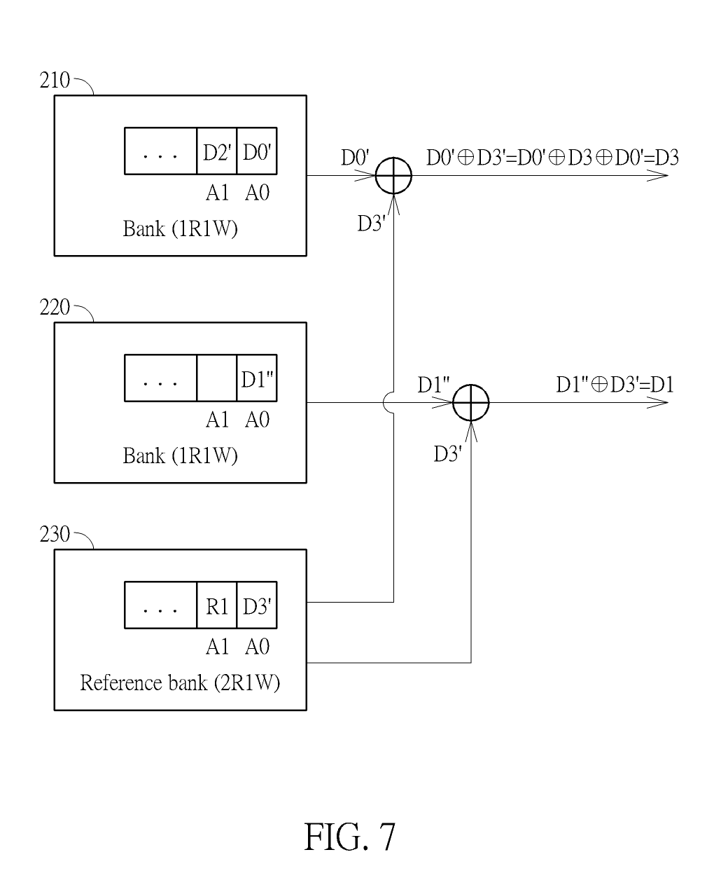

Please refer to FIG. 7, which is a diagram illustrating a method for reading the data stored in the banks 210 and 220 shown in FIGS. 4 and 5 according to one embodiment of the present invention. A shown in FIG. 7, when the memory module 120 receives two read commands and two data D3 and D1 are requested to be read from the banks 210 and 220, respectively, the memory controller 110 reads the encoded data D0′ and the encoded data D3′ from the bank 220 and the reference bank 230, respectively, and the memory controller 110 decodes the encoded data D0′ by using the encoded data D3′ to generate the data D3; and at the same time, memory controller 110 further reads the updated encoded data D1″ and the encoded data D3′ from the bank 210 and the reference bank 230, respectively, and the memory controller 110 decodes the updated encoded data D1″ by using the encoded data D3′ to generate the data D1. In this embodiment, the decoding step is the exclusive-or (XOR) operation, that is D3=D0′^{⊕}D3′, and D1=D1″^{⊕}D3′.

It is noted that the reading operation for the data D3 is the same without any change. That is, the data D3 is also obtained by performing the XOR operation upon the data read from the cells corresponding to the address A0 of the bank 210 and the reference bank 230. In other words, no matter whether the bank conflict occurs or not, the read data in response to the read command is always obtained by decoding the data in the bank 210/220 with the corresponding reference data in the reference bank 230.

Briefly summarizing the above embodiment shown in FIGS. 4-7, when both the two data D2 and D3 are requested to be written into the bank 210, the data D2 can be encoded and written into the bank 210, and the data D3 can be encoded and written into the reference bank 230 to update/overwrite the reference data R0. In addition, because the reference data R0 in the reference bank is updated, the encoded data D1′ corresponding to the reference data R0 also needs to be updated. By using the writing method mentioned above, two data D2 and D3 can be simultaneously written into the memory module 120 while the data D2 and D3 have the bank conflict. Hence, the banks 210 and 220 and the reference bank 230 can form a specific memory module that always supports two write commands (two write ports) even if the banks 210 and 220 only have one write port. That is, this specific memory module increases its write ports. Furthermore, the same read operations are used to read data stored in the specific memory module no matter which one of the writing steps shown in FIGS. 2A and 5 is applied.

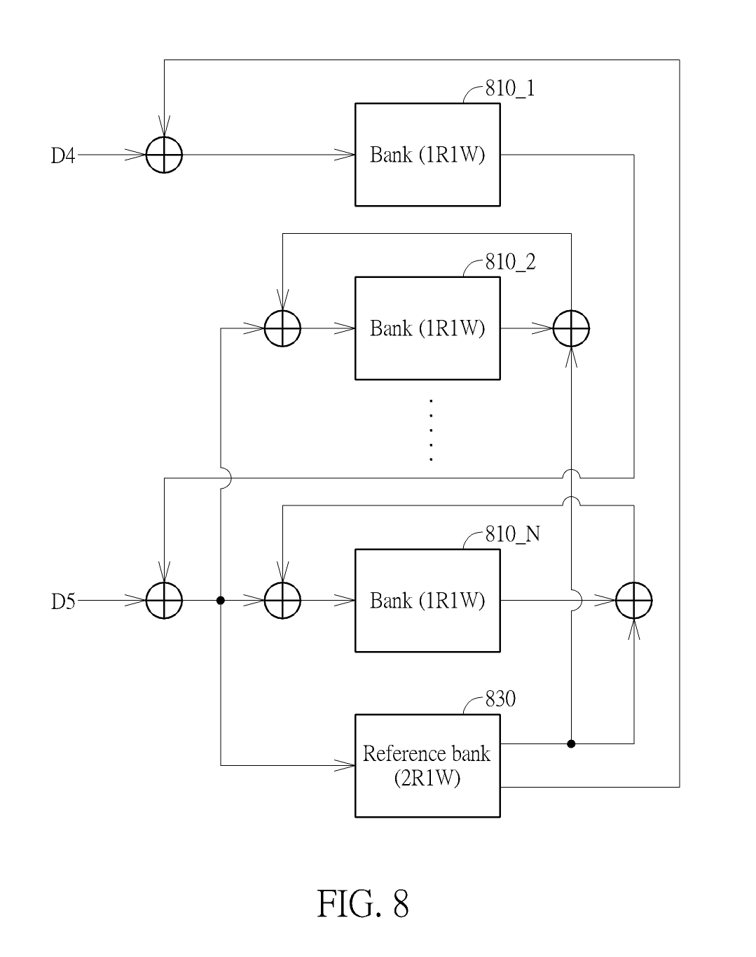

In addition, in the above embodiments shown in FIGS. 2-7, the reference bank 230 is shared by two banks 210 and 230. In other embodiments, the reference bank can be shared by more than two banks. FIG. 8 is a diagram showing operations of banks 810_1-810_N and a reference bank 830, when two data D4 and D5 are asked to be written into the same bank 810_1. Similar to the embodiment shown in FIG. 5, in FIG. 8, when two data D4 and D5 are written into the memory module, the data D4 is encoded and stored into the bank 810_1; meanwhile, the data D5 is encoded and stored into the reference bank 830; and the corresponding data in the banks 810_2-810_N are updated. In other words, when two data D4 and D5 are asked to be written into the bank 810_1 simultaneously, the operations of the bank 810_1 are similar to that of the bank 210 shown in FIG. 5, the operations of the other banks 810_2-810_N1 are similar to that of the bank 220 shown in FIG. 5, and the operations of the reference bank 830 are similar to that of the reference bank 230 shown in FIG. 5. Because a person skilled in the art should understand the embodiments shown in FIG. 8 after reading the embodiments of FIGS. 4-6, further descriptions are therefore omitted here.

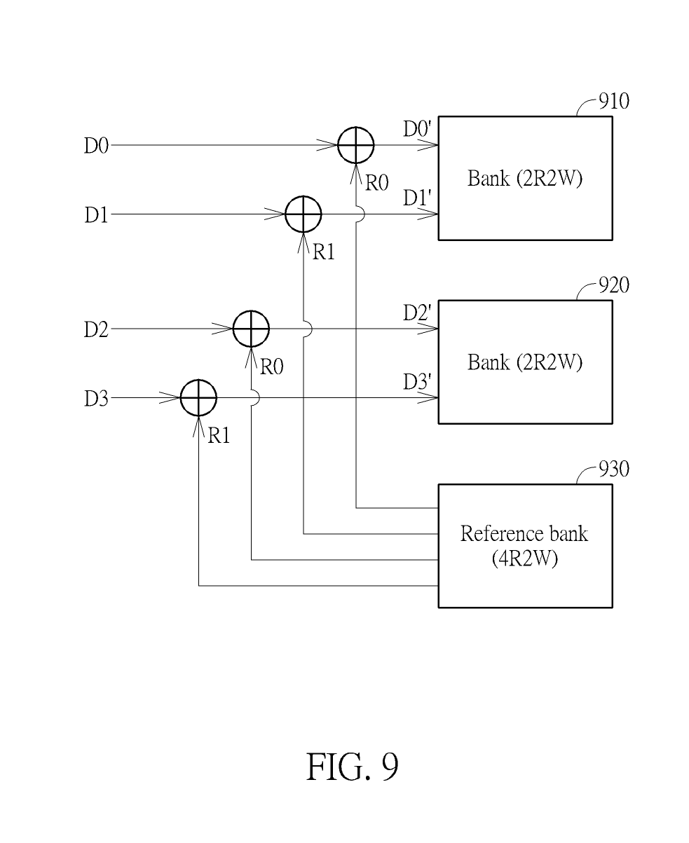

Please refer to FIG. 9, which is a diagram illustrating a method for accessing the memory module 120 according to another embodiment of the present invention. As shown in FIG. 9, the memory module 120 comprises two banks 910 and 920 and a reference bank 930, wherein the banks 910 and 920 are two-read-two-write (2R2W) banks, and the reference bank 930 is a four-read-two-write (4R2W) bank. In this embodiment, the memory module 120 receives four write commands and four data D0-D3 are requested to be written into the banks 910 and 920, wherein the data D0-D1 are requested to be written into the cells corresponding to the addresses A0 and A1 of the bank 910, respectively, and the data D2-D3 are requested to be written into the cells corresponding to the addresses A0 and A1 of the bank 920, respectively. A shown in FIG. 9, the memory controller 110 reads a reference data R0 from an address A0 of the reference bank 930, and the memory controller 110 encodes the data D0 with the reference data R0 to generate the encoded data D0′, and the encoded data D0′ is written into a cell having the address A0 of the bank 910; the memory controller 110 reads a reference data R1 from an address A1 of the reference bank 930, and the memory controller 110 encodes the data D1 with the reference data R1 to generate the encoded data D1′, and the encoded data D1′ is written into a cell having the address A1 of the bank 910; at the same time, the memory controller 110 reads the same reference data R0 from the address A0 of the reference bank 930, and the memory controller 110 encodes the data D2 with the reference data R0 to generate the encoded data D2′, and the encoded data D2′ is written into a cell having the address A0 of the bank 920; and the memory controller 110 reads the same reference data R1 from the address A1 of the reference bank 930, and the memory controller 110 encodes the data D3 with the reference data R1 to generate the encoded data D3′, and the encoded data D3′ is written into a cell having the address A1 of the bank 920. In this embodiment, each of D0, D1, D2, D3, D0′, D1′, D2′, D3′, R0 and R1 is a bit, and the encoding step is the XOR operation.

In addition, in another embodiment, if the data D2-D3 are requested to be written into the cells corresponding to the addresses A2 and A3 of the bank 920, respectively, the memory controller 110 reads the reference data R2 from the address A2 of the reference bank 930, and the memory controller 110 encodes the data D2 with the reference data R2 to generate the encoded data D2′, and the encoded data D2′ is written into a cell having the address A2 of the bank 920; and the memory controller 110 reads the same reference data R3 from the address A3 of the reference bank 930, and the memory controller 110 encodes the data D3 with the reference data R3 to generate the encoded data D3′, and the encoded data D3′ is written into a cell having the address A3 of the bank 920. In this embodiment, each of R2 and R3 is a bit, and the encoding step is the XOR operation.

The embodiment shown in FIG. 9 is a case that the four write commands do not have the bank conflict issue, so the data D0-D3 can be directly and simultaneously written into the banks 910 and 920, respectively, after the encoding steps.

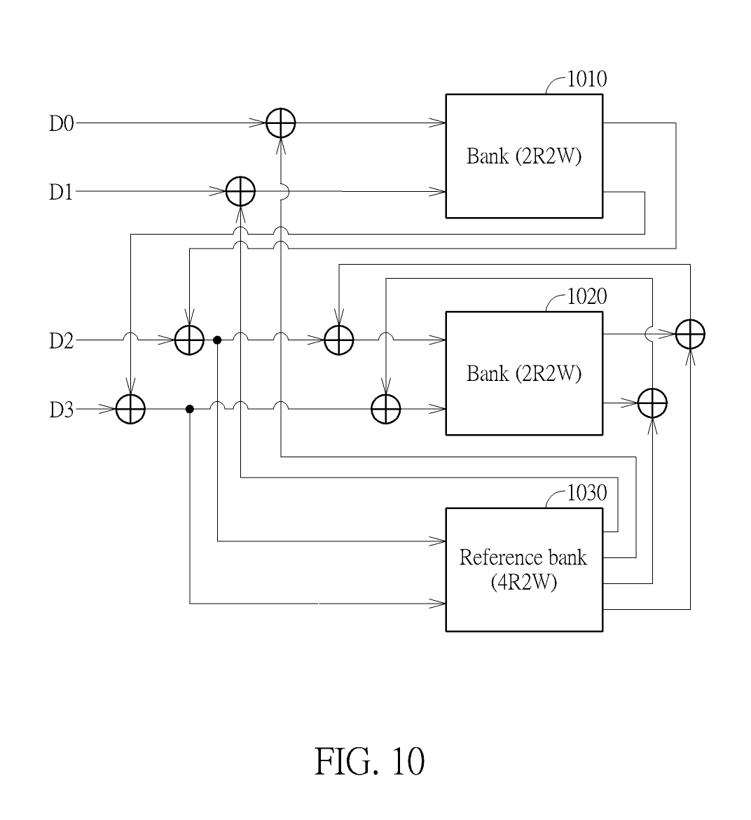

Please refer to FIG. 10, which is a diagram illustrating a method for accessing the memory module 120 according to another embodiment of the present invention. As shown in FIG. 10, the memory module 120 comprises two banks 1010 and 1020 and a reference bank 1030, wherein the banks 1010 and 1020 are two-read-two-write (2R2W) banks, and the reference bank 1030 is a four-read-two-write (4R2W) bank. In this embodiment, the memory module 120 receives four write commands and four data D0-D3 are requested to be written into the bank 1010. Because the bank 1010 merely have two write ports, so only two data can be written into the bank 1010 at the same time. In FIG. 10, the data D0 and D1 are encoded and written into the bank 1010; meanwhile, the data D2 and D3 are encoded by using the old data stored in the bank 1010, and the encoded data of the data D2 and D3 are stored in the cells, whose addresses are the same as the addresses of the old data in the bank 1010, of the reference bank 1030. In addition, because of the update/overwrite of the reference bank 1030, the corresponding data in the bank 1020 are updated accordingly. In other words, the write steps of the data D0 and D1 shown in FIG. 10 are similar to the write steps of the data D2 shown in FIG. 4, and the write steps of the data D2 and D3 shown in FIG. 10 are similar to the write steps of the data D3 shown in FIG. 4. Because a person skilled in the art should understand the embodiments shown in FIG. 10 after reading the embodiments of FIGS. 4-6, further descriptions are therefore omitted here.

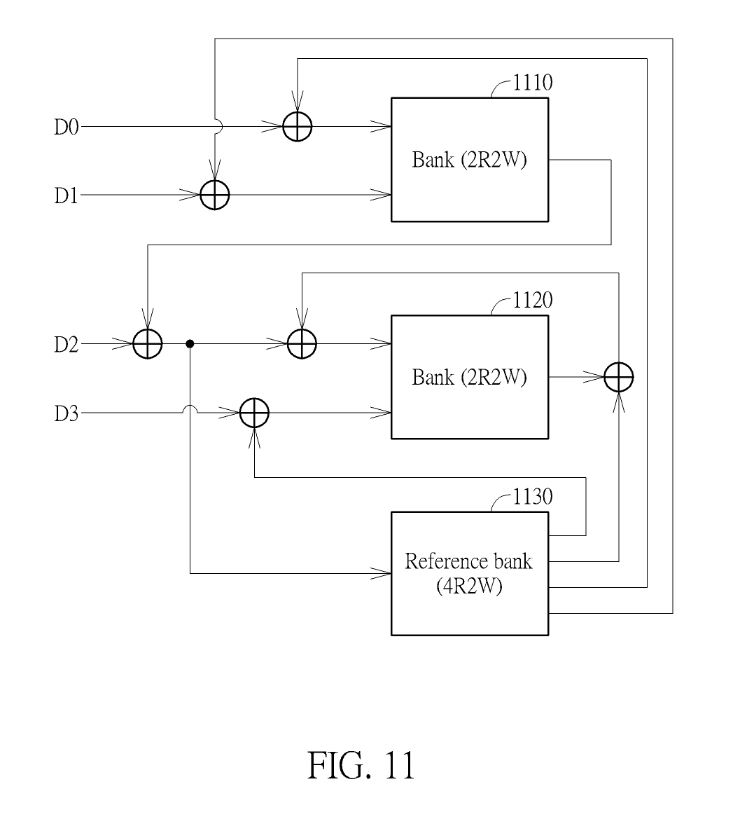

Please refer to FIG. 11, which is a diagram illustrating a method for accessing the memory module 120 according to another embodiment of the present invention. As shown in FIG. 11, the memory module 120 comprises two banks 1110 and 1120 and a reference bank 1130, wherein the banks 1110 and 1120 are two-read-two-write (2R2W) banks, and the reference bank 1130 is a four-read-two-write (4R2W) bank. In this embodiment, the memory module 120 receives four write commands and four data D0-D3 are requested to be written into the banks 1110 and 1120, wherein the data D0-D2 are requested to be written into the bank 1110, and the data D3 is requested to be written into the bank 1120, and the access addresses corresponding to the data D2 and D3 are different (i.e. the cell corresponding to the data D2 in the bank 1110 and the cell corresponding to the data D3 in the bank 1120 have different address). Because the bank 1110 merely have two write ports, so only two data can be written into the bank 1110 at the same time. In FIG. 11, the data D0 and D1 are encoded and written into the bank 1110, and the data D3 is encoded and written into the bank 1120; meanwhile, the data D2 is encoded with the old data stored in the bank 1110, and the encoded data of the data D2 is stored in the cell, whose address is the same as the address of the old data in the bank 1110, of the reference bank 1130. In addition, because of the update/overwrite of the reference bank 1130, the corresponding data in the bank 1120 are updated accordingly. In other words, the write steps of the data D0, D1 and D3 shown in FIG. 11 are similar to the write steps of the data D2 shown in FIG. 4, and the write steps of the data D2 shown in FIG. 11 are similar to the write steps of the data D3 shown in FIG. 4. Because a person skilled in the art should understand the embodiments shown in FIG. 11 after reading the embodiments of FIGS. 4-6, further descriptions are therefore omitted here.

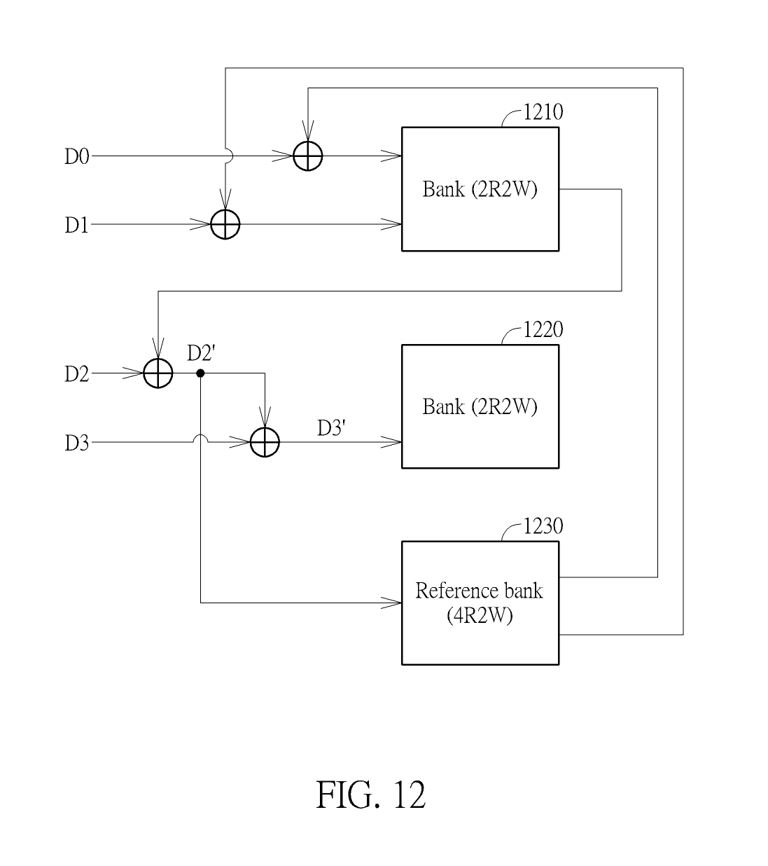

Please refer to FIG. 12, which is a diagram illustrating a method for accessing the memory module 120 according to another embodiment of the present invention. As shown in FIG. 12, the memory module 120 comprises two banks 1210 and 1220 and a reference bank 1230, wherein the banks 1210 and 1220 are two-read-two-write (2R2W) banks, and the reference bank 1230 is a four-read-two-write (4R2W) bank. In this embodiment, the memory module 120 receives four write commands and four data D0-D3 are requested to be written into the banks 1210 and 1220, wherein the data D0-D2 are requested to be written into the bank 1210, and the data D3 is requested to be written into the bank 1220, and the access addresses corresponding to the data D2 and D3 are the same (hereinafter, it is assumed that the same address A3). Because the bank 1210 merely have two write ports, so only two data can be written into the bank 1210 at the same time. In FIG. 12, the data D0 and D1 are encoded and written into the bank 1210; meanwhile, the data D2 is encoded with the old data stored in the cell corresponding the address A3 of the bank 1210 to generate the encoded data D2′, and the encoded data D2′ is stored into the cell corresponding to the address A3 of the reference bank 1230. In addition, the data D3 is encoded with the encoded data D2′ to generate the encoded data D3′, and the encoded data D3′ is stored into the cell corresponding to the address A3 of the bank 1220. In this embodiment, the write steps of the data D0 and D1 shown in FIG. 12 are similar to the write steps of the data D2 shown in FIG. 4, and the write steps of the data D2 shown in FIG. 12 are similar to the write steps of the data D3 shown in FIG. 4. Because a person skilled in the art should understand the embodiments shown in FIG. 12 after reading the embodiments of FIGS. 4-6, further descriptions are therefore omitted here.

Briefly summarizing the above embodiment shown in FIGS. 9-12, By using the writing method mentioned above, four data D0-D3 can be simultaneously written into the memory module 120 no matter whether the bank conflict occurs or not. Hence, the banks 910/1010/1110/1210 and 920/1020/1120/1220 and the reference bank 930/1030/1130/1230 can form a specific memory module that always supports four write commands (four write ports) even if the banks 910/1010/1110/1210 and 920/1020/1120/1220 only have two write ports. That is, this specific memory module increases its write ports. Furthermore, the same read operations are used to read data stored in the specific memory module no matter which one of the writing steps shown in FIGS. 9-12 is applied.

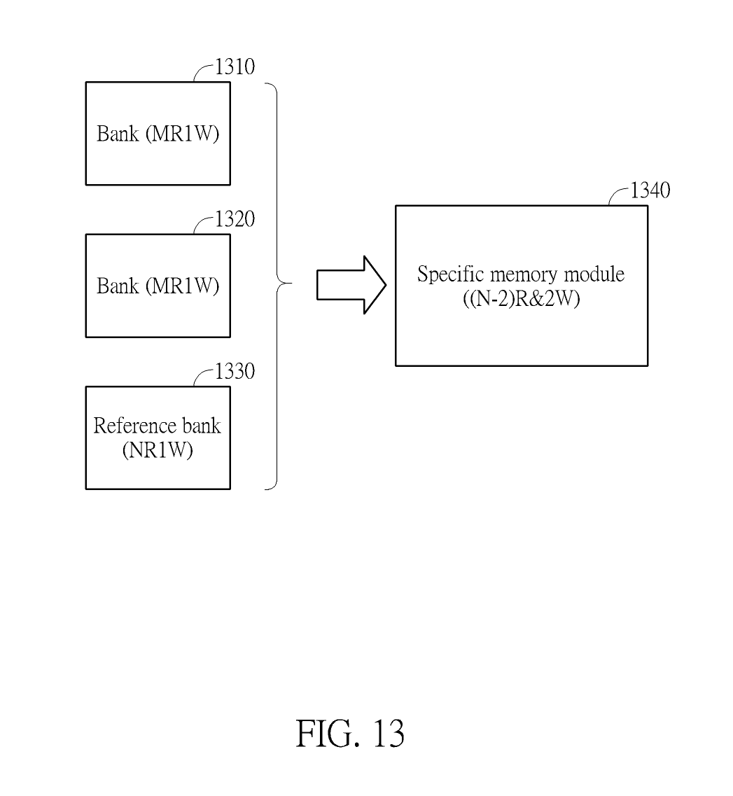

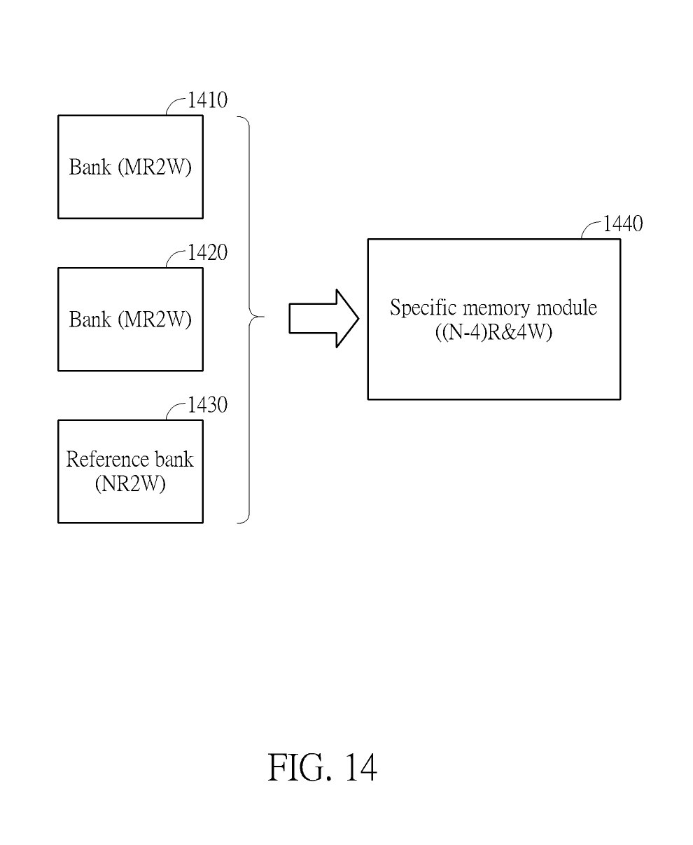

In addition, when the above write steps are used to extend/increase the write ports of the memory module 120, because some data of the reference bank are required to be read for the encoding and decoding steps, the overall read ports of the memory module may be decreased. For example, as shown in FIG. 13, assuming that banks 1310 and 1320 are M-read-one-write (MR1W) bank, and a reference bank 1330 is a N-read-one-write (NR1W) bank, wherein M may be any suitable value less than or equal to N, by using the above-mentioned writing steps, the banks 1310 and 1320 and the reference bank 1330 can form a specific memory module 1340 that have (N-2) read ports and two write ports. For another example, as shown in FIG. 14, assuming that banks 1410 and 1420 are M-read-two-write (MR2W) bank, and a reference bank 1430 is a N-read-two-write (NR1W) bank, wherein M may be any suitable value less than or equal to N, by using the above-mentioned writing steps, the banks 1410 and 1420 and the reference bank 1430 can form a specific memory module 1440 that have (N-4) read ports and four write ports. In light of above, although the read ports are decreased, the write ports of the memory module can be doubled to allow more write commands executed simultaneously.

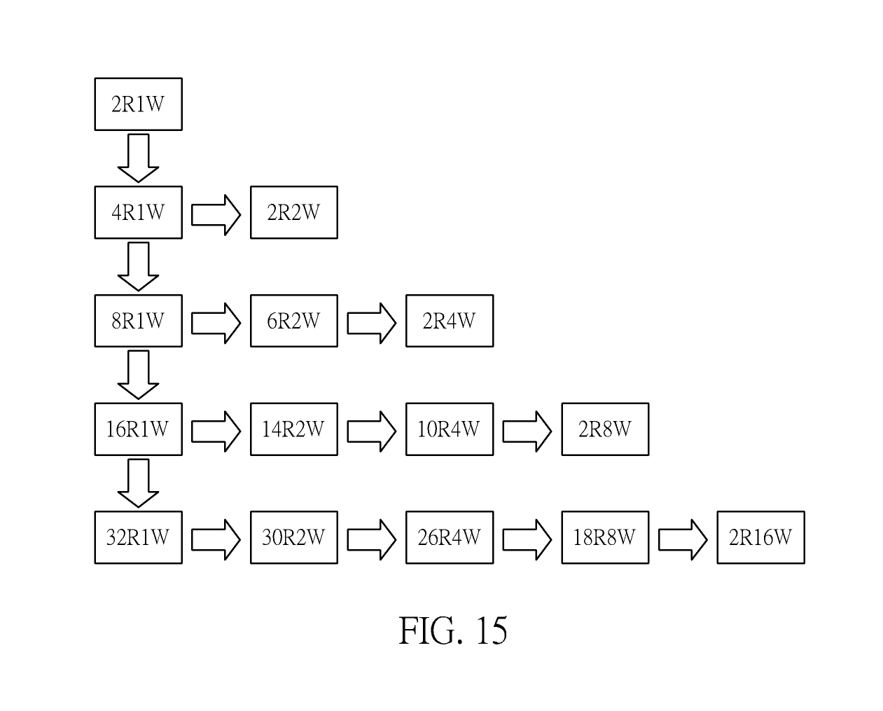

In addition, the read ports of the bank or memory module can be doubled by the conventional art such as using extra layers, for example, a 2R1W bank can extend to be a 4R1W bank, the 4R1W bank extend to be a 8R1W bank, and the 8R1W bank extend to be a 16R1W bank, a person skilled in the art should understand the embodiments and further descriptions are therefore omitted here. Therefore, by using this read ports extension technique and the writing steps of the above-mentioned embodiments, the memory module can have more write ports to execute many write commands simultaneously. Taking FIG. 15 as an example, the 4R1W bank/memory module can extend to 2R2W bank/memory module; the 8R1W bank/memory module can extend to 6R2W bank/memory module or 2R4W bank/memory module; the 16R1W bank/memory module can extend to 14R2W bank/memory module or 10R4W bank/memory module or 2R8W bank/memory module; and the 32R1W bank/memory module can extend to 30R2W bank/memory module or 26R4W bank/memory module or 18R8W bank/memory module or 2R16W bank/memory module etc.

Briefly summarized, by using the accessing method of the embodiments of the present invention, the write ports of the memory module can be increased while the internal banks only have less write ports. In addition, in the embodiments of the present invention, the reference bank is shared by two or more banks for storing data, so the manufacturing cost may not increase too much.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for accessing a multi-port memory module comprising a plurality of banks, wherein the plurality of banks comprise at least a first bank, a second bank and a reference bank, and the method comprises:
when first data is requested to be written into the first bank, reading reference data from the reference bank, and encoding the first data with the reference data to generate first encoded data, and writing the first encoded data into the first bank; and
when second data is requested to be written into the second bank, reading the same reference data from the reference bank, and encoding the second data with the reference data to generate second encoded data, and writing the second encoded data into the second bank.

2. The method of claim 1, further comprising:
when third data is requested to be written into the first bank to update/overwrite the first encoded data of the first bank, but write port(s) of the first bank is occupied by another write process, reading the first encoded data from the first bank, and encoding the third data with the first encoded data to generate third encoded data, and writing the third encoded data into the reference bank to update/overwrite the reference data.

3. The method of claim 2, further comprising:
before the reference data is updated/overwritten by the third encoded data, reading the reference data and the second encoded data from the reference bank and second bank, respectively, and decoding the second encoded data by using the reference data to generate the second data;
encoding the second data with the third encoded data to generate an updated second encoded data; and
writing the updated second encoded data to the second bank to update the second encoded data.

4. The method of claim 2, wherein when the third data is requested to be read from the first bank, reading the first encoded data and the third encoded data from the first bank and the reference bank, respectively, and decoding the third encoded data by using the first encoded data to generate the third data.

5. The method of claim 1, further comprising:
when third data and fourth data are requested to be written into the first bank to update/overwrite first old data and second old data, respectively, reading another reference data from the reference bank, and encoding the third data with the reference data to generate third encoded data, and writing the third encoded data into the first bank to update the first old data; and
reading the second old data from the first bank, and encoding the fourth data with the second old data to generate fourth encoded data, and writing the fourth encoded data into the reference bank to update/overwrite yet another reference data corresponding to the second old data.

6. The method of claim 1, wherein the first bank comprises K write ports, the second bank comprises K write ports, the reference bank comprises N read ports; and the first bank, the second bank and the reference bank form a specific memory sub-module that supports (2*K) write ports and (N-2*K) read ports, wherein K is equal to or greater than one, and N is greater than (2*K).

7. The method of claim 1, wherein each of the first data, the second data and the reference data is a bit, and the encoding operation is an exclusive-or (XOR) operation.

8. A memory controller coupled to a multi-port memory module comprising a plurality of banks, wherein the plurality of banks comprise at least a first bank, a second bank and a reference bank, and when first data is requested to be written into the first bank, the memory controller is arranged to read reference data from the reference bank, and encode the first data with the reference data to generate first encoded data, and write the first encoded data into the first bank ; and when second data is requested to be written into the second bank, the memory controller is arranged to read the same reference data from the reference bank, and encode the second data with the reference data to generate second encoded data, and write the second encoded data into the second bank.

9. The memory controller of claim 8, wherein when third data is requested to be written into the first bank to update/overwrite the first encoded data of the first bank, but write port(s) of the first bank is occupied by another write process, the memory controller reads the first encoded data from the first bank, and encodes the third data with the first encoded data to generate third encoded data, and writes the third encoded data into the reference bank to update/overwrite the reference data.

10. The memory controller of claim 9, wherein before the reference data is updated/overwritten by the third encoded data, the memory controller reads the reference data and the second encoded data from the reference bank and second bank, respectively, and decodes the second encoded data by using the reference data to generate the second data; and the memory controller further encodes the second data with the third encoded data to generate an updated second encoded data, and writes the updated second encoded data to the second bank to update the second encoded data.

11. The memory controller of claim 9, wherein when the third data is requested to be read from the first bank, the memory controller reads the first encoded data and the third encoded data from the first bank and the reference bank, respectively, and decodes the third encoded data by using the first encoded data to generate the third data.

12. The memory controller of claim 8, wherein when third data and fourth data are requested to be written into the first bank to update/overwrite first old data and second old data, respectively, the memory controller reads another reference data from the reference bank, and encodes the third data with the reference data to generate third encoded data, and writes the third encoded data into the first bank to update the first old data; and the memory controller further reads the second old data from the first bank, and encodes the fourth data with the second old data to generate fourth encoded data, and writes the fourth encoded data into the reference bank to update/overwrite yet another reference data corresponding to the second old data.

13. The memory controller of claim 8, wherein the first bank comprises K write ports, the second bank comprises K write ports, the reference bank comprises N read ports; and the first bank, the second bank and the reference bank form a specific memory sub-module that supports (2*K) write ports and (N-2*K) read ports, wherein K is equal to or greater than one, and N is greater than (2*K).

14. The memory controller of claim 8, wherein each of the first data, the second data and the reference data is a bit, and the encoding operation is an exclusive-or (XOR) operation.

15. A method for increasing write ports of a memory module, comprising:
providing a first bank and a reference bank within the memory module;
when both first data and second data are requested to be written into the first bank, but the second data is not allowed to be written into the first bank to update/overwrite old data simultaneously, reading first reference data from the reference bank, encoding the first data with the first reference data to generate first encoded data, and writing the first encoded data into the first bank; and
reading the old data from the first bank, encoding the second data with the old data to generate second encoded data, and writing the second encoded data into the reference bank to update/overwrite second reference data corresponding to the old data.

16. The method of claim 15, herein the first bank comprises K write ports, and the reference bank comprises N read ports, the memory module supports (2*K) write ports and (N-2*K) read ports, wherein K is equal to or greater than one, and N is greater than (2*K).

17. The method of claim 15, further comprising:
providing a second bank within the memory module;
when third data is requested to be written into the second bank, reading the first reference data from the reference bank, encoding the third data with the first reference data to generate a third encoded data, and writing the third encoded data into the second bank.

18. The method of claim 15, wherein each of the first data, the second data and the reference data is a bit, and the encoding operation is an exclusive-or (XOR) operation.

19. The method of claim 15, wherein each bank is allowed to be accessed independently.

20. The method of claim 15, wherein the memory module is a multi-port static random access memory (SRAM) module or a multi-port dynamic random access memory (DRAM).
